(19) United States
(12) Patent Application Publication
(10) Pub. No.: US 2022/0231651 A1
(43) Pub. Date: Jul. 21, 2022

(54) METHOD FOR FORMING FILM BULK ACOUSTIC RESONATOR

(71) Applicant: NINGBO SEMICONDUCTOR INTERNATIONAL CORPORATION (SHANGHAI BRANCH), Shanghai (CN)

(72) Inventor: Hailong LUO, Ningbo, Zhejiang (CN)

(21) Appl. No.: 17/614,991

(22) PCT Filed: Sep. 23, 2019
(86) PCT No.: PCT/CN2019/107175

§ 371 Date: Nov. 29, 2021

(30) Foreign Application Priority Data
Jul. 19, 2019 (CN) 201910656733.3

(51) Int. Cl. H03H 3/02; H03H 9/17; H03H 9/05

(52) U.S. Cl. CPC H03H 3/02; H03H 9/0504; H03H 9/17

(57) ABSTRACT

In a method for forming a film bulk acoustic resonator (FBAR), a bulk acoustic wave (BAW) film stack (120) and a support structure (130) are successively formed on a first substrate (100). The support structure (130) includes a primary support wall (131), an isolation wall (132) internal to the primary support wall (131) and a secondary support pillar (133) internal to the isolation wall (132). After a second substrate (200) is bonded and the first substrate (100) is removed, the secondary support pillar (133) and the isolation wall (132) are removed through a release window (120a) in an area delimited by the isolation wall (132). The secondary support pillar (133) contributes to effective support provided during transfer of the films and any other process carried out above the support structure, the isolation wall (132) between the primary support wall (131) and the secondary support pillar (133) can protect the primary support wall (131) against erosion during a process for removing the secondary support pillar (133), providing for high reliability of a cavity (140) subsequently formed within an area delimited by the primary support wall (131).

### TECHNICAL FIELD

The present invention relates to the technical field of filters and, more specifically, to a method for forming a film bulk acoustic resonator (FBAR).

### BACKGROUND

The ever-developing wireless communication technology requires various wireless communication terminals to be versatile and able to transfer data over different frequency spectrums. In addition, in order to support a sufficient data rate with a limited bandwidth, it also places demanding requirements on the performance of radio-frequency (RF) systems. As a key component of RF systems, RF filters are used to filter out interference and noise that are not in their communication spectra and thus provide for a signal-to-noise ratio as required by the RF systems and communication protocols. For example, it may be necessary for a mobile phone to incorporate tens of filters, each for a frequency band in which the mobile phone may operate.

Filters are typically constructed from inductors, capacitors and resonators. In resonators operating based on piezoelectricity, an acoustic wave resonates in a piezoelectric material and is then converted into an electric wave for use. Among piezoelectric resonators, different numbers of bulk acoustic wave (BAW) resonators can be cascaded to form BAW filters that satisfy various performance requirements. As a subcategory of BAW resonators, film bulk acoustic resonators (FBAR) include a BAW film stack seated over a cavity that is formed in a substrate to serve as a reflector. The BAW film stack generally includes a piezoelectric film sandwiched between two electrodes, and an acoustic wave resonates in the piezoelectric film at a frequency depending on the material thereof. Thanks to a wide range of advantages including a high quality factor (Q-factor), ability to integrate to an IC chip and compatibility with CMOS fabrication processes, FBARs have undergone rapid development in recent years.

An existing FBAR fabrication method involves etching a substrate to form therein a recess and filling a sacrificial material therein. A BAW film stack is then formed over the sacrificial material, and a window is opened in the stack using an etching process, followed by removal of the sacrificial material via the window. In this method, since the BAW film stack is formed over the sacrificial material, surface roughness of the underlying material is critical to the performance of the stack. Therefore, particular care must be taken in roughness control, making the overall process complicated. In addition, it is difficult for this method to result in a high-quality monocrystalline piezoelectric film that is crucial to the performance of the resulting FBAR.

Instead of using a sacrificial material, another existing FBAR fabrication method involves fabricating a BAW film stack directly on a substrate and a support structure on the BAW film stack, bonding the whole to another substrate via the support structure, and removing the first substrate so that electrodes are separated and remain over a cavity. In order to provide sufficient support to the BAW film stack, in addition to support walls that delimit the cavity, the support structure also includes secondary support pillars that are formed inside the cavity and removed after the completion of the resonator. However, a process for removing the support pillars tends to etch away part of the support walls and thus impair the resonator's performance.

### SUMMARY OF THE INVENTION

In view of the problems with the conventional methods, the present invention proposes a method for forming a film bulk acoustic resonator (FBAR) with improved reliability using a simpler process.

The proposed method comprises the steps of: providing a first substrate; forming an isolation layer on the first substrate and a bulk acoustic wave (BAW) film stack on the isolation layer; forming a support structure comprising an primary support wall, an isolation wall internal to the primary support wall, and a secondary support pillar internal to the isolation wall, which are disposed across a top surface of the BAW film stack, both the primary support wall and the isolation wall being annular, the isolation wall surrounded by the primary support wall, the secondary support pillar in turn surrounded by the isolation wall; bonding a side of the first substrate with the support structure formed thereon to a second substrate and removing the first substrate; forming a release window in the BAW film stack, which brings a space delimited by the isolation wall into communication with the outside; and removing both the secondary support pillar and the isolation wall via the release window.

In the proposed method, the secondary support pillar contributes to effective support provided during transfer of the films and any other process carried out above the support structure, and the isolation wall between the primary support wall and the secondary support pillar can minimize or eliminate the possibility of the primary support wall being eroded during a process for removing the secondary support pillar, providing for high reliability of a cavity subsequently formed within an area demarcated by the primary support wall and improved resonant performance of the fabricated FBAR.

### BRIEF DESCRIPTION OF THE DRAWINGS

FIG. 1 is a flowchart schematically illustrating a method for forming a film bulk acoustic resonator (FBAR) according to embodiments of the present invention.

FIGS. 2 to 8 are schematic cross-sectional views of structures resulting from steps in a method for forming an FBAR according to embodiments of the present invention.

In these figures,

100 denotes a first substrate; 200, a second substrate; 110, an isolation layer; 120, a BAW film stack; 121, a first electrode layer; 122, a piezoelectric layer; 123, a second electrode layer; 130, a support structure; 131, a primary support wall; 132, an isolation wall; 133, a secondary support pillar; 123a, a peripheral trimmed region; 120a, a release window; and 140, a cavity.

### DETAILED DESCRIPTION

BAW resonator fabrication methods provided in the present invention will be described below in greater detail with reference to particular embodiments and to the accompanying drawings. Features and advantages of the invention will be more apparent from the following description. Note that the figures are provided in a very simplified form not necessarily drawn to exact scale for the only purpose of helping to explain the disclosed exemplary embodiments in a more convenient and clearer way. Embodiments of the invention should not be construed as limited to the particular shapes of the regions illustrated in the figures. For the sake of clarity, throughout the figures that help illustrate the embodiments disclosed herein, like elements are in principle labeled with like reference numbers, and repeated descriptions thereof are omitted.

It is to be understood that the terms “first”, “second” and so on, as used hereinafter, may be used to distinguish between similar elements without necessarily implying any particular ordinal or chronological sequence. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

FIG. 1 is a flowchart schematically illustrating a method of forming a film bulk acoustic resonator (FBAR) according to embodiments of the present invention. Referring to FIG. 1, the method includes the steps of:

(S1) providing a first substrate;

(S2) forming an isolation layer on the first substrate and a BAW film stack on the isolation layer;

(S3) forming a support structure comprising an primary support wall, an isolation wall internal to the primary support wall, and a secondary support pillar internal to the isolation wall, which are disposed across a top surface of the BAW film stack, both the primary support wall and the isolation wall being annular, the isolation wall surrounded by the primary support wall, the secondary support pillar in turn surrounded by the isolation wall;

(S4) bonding the side of the first substrate where the support structure is formed to a second substrate and removing the first substrate;

(S5) forming a release window in the BAW film stack, which brings a space delimited by the isolation wall into communication with the outside; and

(S6) removing the secondary support pillar and the isolation wall via the release window.

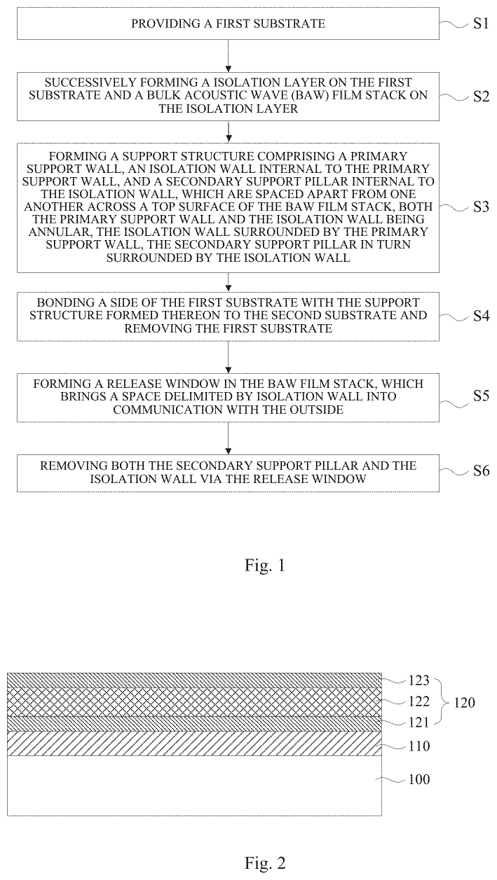

FIGS. 2 to 8 are schematic cross-sectional views of structures resulting from steps in a method of forming an FBAR according to embodiments of the present invention. This method will be described in greater detail below with reference to FIGS. 2 to 8.

First of all, in step S1, a first substrate 100 is provided. In the illustrated embodiment, the first substrate 100 serves to bear both the subsequent-fabricated BAW film stack and support structure.

The first substrate 100 may be selected from device substrates and carrier substrates commonly used in the art. Specifically, the first substrate 100 may be fabricated from any suitable substrate material well known to those skilled in the art. Examples of such materials may include at least one of silicon (Si), germanium (Ge), silicon germanium (SiGe), silicon carbide (SiC), silicon germanium carbide (SiGeC), indium arsenide (InAs), gallium arsenide (GaAs), indium phosphide (InP) or other III-V compound semiconductors. Alternatively, the substrate may be a multilayer structure or the like of one or more of those materials. Still alternatively, it may be a silicon on insulator (SOI), strained silicon on insulator (SSOI), strained silicon germanium on insulator (S—SiGeOI), silicon germanium on insulator (SiGeOI), germanium on insulator (GeOI), double side polished (DSP), alumina or like ceramic, quartz, glass or like substrate. In the illustrated embodiment, the first substrate 100 may be, for example, a P-type high-resistance monocrystalline silicon wafer with a (100) crystal plane on the top side. Of course, the first substrate 100 may include any other suitable material known in the art.

FIG. 2 shows a schematic cross-sectional view of a structure resulting from the formation of a BAW film stack in the method according to an embodiment of the present invention. Referring to FIGS. 1 and 2, in step S2, an isolation layer 110 is formed on the first substrate 100 and a BAW film stack 120 on the isolation layer 110.

The isolation layer 110 on the first substrate 100 may serve as a buffer material for the BAW film stack 120 and may be formed on the first substrate 100 using a suitable method (e.g., chemical vapor deposition, physical vapor deposition, atomic layer deposition, coating, thermal oxidation method, etc.). The isolation layer 110 may be made of any suitable material that can be easily coated on the first substrate 100 but does not easily react with the subsequent-formed BAW film stack 120, such as a dielectric material including, but not limited to, at least one of silicon oxide, silicon nitride, silicon oxynitride, aluminum oxide, aluminum nitride, titanium oxide, titanium nitride, fluorocarbon, carbon-doped silicon oxide, silicon carbide nitride and the like. In other embodiments, the isolation layer 110 may be made of any suitable material that can be easily coated on the first substrate 100 but does not easily react with the subsequent-formed BAW film stack 120, such as amorphous carbon, a light-curing adhesive, a hot melt adhesive, a laserable bonding layer (e.g., a polymer), etc. Advantageously, the isolation layer 110 can mitigate any adverse impact of possible defects present on the surface of the first substrate 100 on the BAW film stack 120, thus helping improve the performance and reliability of the device being fabricated. Moreover, during the subsequent removal of the first substrate 100 using a backside thinning process (e.g., chemical mechanical planarization), the isolation layer 110 can facilitate controlling stopping point for the etching process for removing the first substrate 100, avoiding possible damage to the subsequently-formed BAW film stack 120. The isolation layer 110 may have a thickness in the range of from 0.1 μm to 2 μm, optionally below 1 μm.

The isolation layer 110 may include an upper etch stop layer (not shown) and a sacrificial layer (not shown) between the etch stop layer and the first substrate 100. The etch stop layer in the isolation layer 110 may have a relatively small thickness (e.g., 1000 Å), and each of the sacrificial layer and the subsequently-formed BAW film stack 120 (more exactly, the electrode layer closer to the first substrate 100) exhibit a high etch rate ratio to the etch stop layer. This provides for a stop point for the subsequent process for separating the BAW film stack 120 from the first substrate 100, which can avoid unwanted damage to the BAW film stack 120 during the removal of the first substrate 100. For example, the etch stop layer may be made of silicon oxide, silicon nitride or silicon oxynitride. The sacrificial layer in the isolation layer 110 may be any suitable material that allows easy separation of the BAW film stack 120 from the first substrate 100 using a simpler process.

Referring to FIG. 2, in the illustrated embodiment, the BAW film stack 120 may include a first electrode layer 121, a piezoelectric layer 122 and a second electrode layer 123, which are sequentially stacked one above another away from the isolation layer 10. The first electrode 121, piezoelectric 122 and second electrode 123 layers may have either the same or different shapes or areas. When the resonator is subsequently completed by patterning the first and second substrates 100, 200 that are bonded together, the remainders of the first and second electrode layers 121, 123 remaining from the patterning process may provide top and bottom electrodes of the resonator, respectively. In other non-limiting embodiments of the present invention, the BAW film stack 120 may also include other film(s), in addition to the first electrode layer 121, the piezoelectric layer 122 and the second electrode layer 123, as appropriately required by the device being fabricated.

The first and second electrode layers 121 and 123 may be each made of any suitable conductive or semiconductor material known to those skilled in the art. The conductive material may be a metal material with conductive properties. For example, each of the layers may consist of a single layer or a stack of layers of one or more of molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), silver (Ag), gold (Au), osmium (Os), rhenium (Re), palladium (Pd), tin (Sn) and other metals. The semiconductor material may be, for example, Si, Ge, SiGe, SiC, SiGeC or the like. The first and second electrode layers 121 and 123 may be formed using a physical vapor deposition technique, such as magnetron sputtering or evaporation, or using a chemical vapor deposition technique. Preferably, the first and second electrode layers 121 and 123 may be formed of the same material. However, in practice, they may also be constructed from different conductive materials, as actually needed. The piezoelectric layer 122, that can be also referred to as a piezoelectric resonator layer or a piezoelectric resonator structure, may be fabricated from one or more piezoelectric materials such as quartz, aluminum nitride (AlN), zinc oxide (ZnO), lead zirconate titanate (PZT), lithium niobate (LiNbO3), lithium tantalate (LiTaO3), etc. The piezoelectric layer 122 may be further doped with one or more rare-earth elements. In the illustrated embodiment, the first and second electrode layers 121 and 123 are for example molybdenum layers, and the piezoelectric layer 122 is for example an aluminum nitride layer. The first and second electrode layers 121 and 123 may each have a thickness in the range of approximately 100-200 nm, and the piezoelectric layer 122 may have a thickness ranging from 1 μm to 3 μm, depending on the desired resonant frequency. For example, the thickness of the piezoelectric layer 122 may be configured to be equal to ½ of the resonant wavelength. Each molybdenum layer may be deposited using physical vapor deposition (PVD) or magnetron sputtering, and the aluminum nitride layer may be deposited using PVD or metal organic chemical vapor deposition (MOCVD).

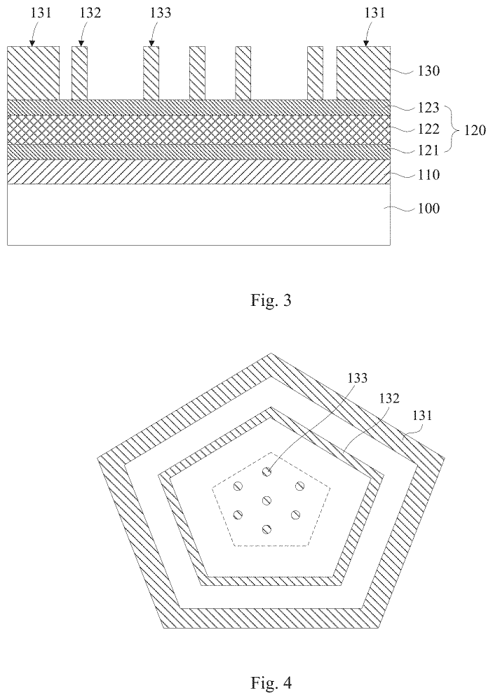

FIG. 3 shows a schematic cross-sectional view of a structure resulting from the formation of a support structure in the method according to an embodiment of the present invention. FIG. 4 is a schematic top view of the support structure of FIG. 3. Referring to FIGS. 3 and 4, in step S3, a support structure 130 including a primary support wall 131, an isolation wall 132 internal to the primary support wall 131, and a secondary support pillar 133 internal to the isolation wall 132 is formed, which are spaced from one another across a top surface of the BAW film stack 120. The primary support wall 131 and the isolation wall 132 are both annular walls, and the isolation wall 132 is surrounded by the primary support wall 131, with the secondary support pillar 133 being in turn surrounded by the isolation wall 132. The support structure 130 may be formed by depositing and patterning a support material over the second electrode layer 123. The support material may be any suitable material that does not easily react with the BAW film stack. Non-limiting examples of the support material may include, but are not limited to, silicon nitride, silicon oxynitride, aluminum oxide, aluminum nitride, titanium oxide, titanium nitride, amorphous carbon, tetraethyl orthosilicate, etc. or a combination thereof. The support material may also be, for example, a dry film or any other suitable material well-known in the art. The support material may include a laminate of two or more materials. The support material may also be selected as at least one material with high mechanical strength such as silicon oxide, silicon nitride, silicon oxynitride, etc. In this case, the pillar in the support structure 130 can provide sufficient support to enhance structural integrity of the device and avoid undesirable deformation or breakage of the BAW film stack in a subsequent process due to a pressure difference between inside and outside of the cavity. In addition, risk of current leakage can be reduced, and adhesion can be enhanced, between the BAW film stack and the subsequently-bonded second substrate, resulting in a further increase in the performance and reliability of the device being fabricated.

The support structure 130 demarcates an area of the subsequently-formed air cavity (referred to as the “cavity” hereinafter for short) of the resonator on the first substrate 100. This is made possible using a simple and easily controllable process without involving the formation and removal of a sacrificial layer. In the illustrated embodiment, the outermost primary support wall 131 in the support structure 130 is formed on the BAW film stack 120 to demarcate the location and area of the cavity of the BAW resonator. The primary support wall 131 may have a cross section parallel to the surface of the first substrate 100 in the shape of a rectangle, a circle, a pentagon, a hexagon or the like. The isolation wall 132 and the secondary support pillar 133 located within the area demarcated by the primary support wall 131 are formed to enhance the support to the BAW film stack during the bonding of the first substrate 100 to the second substrate 200, transfer of the stack and the formation of the resonator until the resonator is packaged. This helps ensure sufficient reliability of the film stack to avoid undesirable collapse and allow for reduced process control complexity. Located within an area demarcated by the isolation wall 132, at least one secondary support pillar 133 may be each formed as a solid pillar. For example, two or more secondary support pillars 133 each in the form as a column may be distributed equidistantly within the area demarcated by the isolation wall 132 to provide additional support, or at least one secondary support pillar 133 in the form of a continuous or non-continuous annulus spaced apart from the isolation wall 132 is disposed within the area demarcated by the isolation wall 132 to provide additional support. The following description will be made in the context of an example in which secondary support pillars 133 each in the form of a column are provided in such a manner that each of them is spaced apart from any adjacent secondary support pillar 133 and from the isolation wall 132 that is in turn spaced apart from the primary support wall 131. With support from both the primary support wall 131 and the isolation wall 132, the overlying films can be retained stably. Each secondary support pillar 133 may have a cross section parallel to the first substrate 100 in the shape of one or combinations of a circle, an ellipse, a quadrilateral, a pentagon and a hexagon. In the case of at least two secondary support pillars 133 being provided, they may assume either the same or different shapes. In addition, along a certain direction, these secondary support pillars 133 may be sized either equally or not. In the illustrated embodiment, each secondary support pillar 133 has a rectangular longitudinal cross section (see FIG. 3), i.e., maintains a constant width from bottom to top. However, in particular embodiments, each secondary support pillar 133 may have an otherwise-shaped, e.g., regular or inverted trapezoidal, longitudinal cross section than a rectangular one, with the objects of the present invention being still achieved. Optionally, two or more identically shaped secondary support pillars 133 may be uniformly distributed within the area demarcated by the isolation wall 132 in order to provide more uniform support in the subsequent course of the completion of the resonator following the removal of the first substrate 100.

The isolation wall 132 is situated between the primary support wall 131 and the secondary support pillars 133, and has an annular shape. In a subsequent process for removing the secondary support pillars 133, a gaseous or liquid etchant may be introduced via a release window formed within the area demarcated by the isolation wall 132 so that the etchant acts primarily on the secondary support pillars 133 and isolation wall 132 located within the area. Additionally, diffusion of the gaseous or liquid etchant toward the primary support wall 131 is blocked by the isolation wall 132, significantly reducing the possibility of the primary support wall 131 being (e.g., laterally) etched. Since the primary support wall 131 is substantially prevented from erosion or damage, an improved integrity of the cavity (serving as a resonant cavity of the BAW resonator) that is delimited by the primary support wall 131 is achieved, which is favorable to the performance of the BAW resonator.

The primary support wall 131, isolation wall 132 and secondary support pillars 133 in the support structure 130 may be configured to have equal heights in order to act simultaneously to provide support jointly. In the illustrated embodiment, the primary support wall 131, isolation wall 132 and secondary support pillars 133 in the support structure 130 may be all about 3 μm high. However, the present invention is not so limited, because depending on the material used and on the process tolerance as well as a difference in distance between the top contact interface and the bottom contact interface, the support structure 130 may be somewhat elastic and allow height differences between top surfaces of the primary support wall 131, isolation wall 132 and secondary support pillars 133. Additionally, since the isolation wall 132 is intended mainly to protect the primary support wall 131 during the removal of the secondary support pillars, it is reasonable to allow it to be shorter than the primary support wall 131 and the secondary support pillars 133. The spacings between, and dimensions of, the primary support wall 131, isolation wall 132 and secondary support pillars 133 may also be designed according to practical process and structure constraints. For example, the isolation wall 132 may have a thickness designed according to both the number of the secondary support pillars and how difficult the secondary support pillars are to be etched away. Optionally, in a thickness-wise direction of the primary support wall 131, dimensions of the secondary support pillars 133 and isolation wall 132 may be smaller than, e.g., equal to ⅓ or less of, the thickness of the primary support wall 131. This is favorable to quick removal of both the secondary support pillars 133 and the isolation wall 132 in a subsequent process, with reduced or eliminated adverse impact on the primary support wall 131. If necessary, more than one isolation wall 132 may be provided. For example, in another embodiment, in the support structure on the BAW film stack 120, two or three isolation walls 132 may be arranged one within another between the primary support wall 131 and the secondary support pillars 133. In the illustrated embodiment, each of the primary support wall 131 and isolation wall 132 has a rectangular longitudinal cross section in a thickness-wise direction (see FIG. 3), i.e., maintains a constant width from bottom to top. However, in particular embodiments, each of the primary support wall 131 and isolation wall 132 may have an otherwise-shaped, e.g., regular or inverted trapezoidal, longitudinal cross section in the thickness-wise direction than a rectangular one, with the objects of the present invention being still achieved.

During a subsequent etching process for removing the secondary support pillars 133 from the support structure 130, an inner surface of the isolation wall 132 facing the secondary support pillars 133 will also be etched. In order to ensure complete removal of the secondary support pillars 133 with minimized impact on the primary support wall 131, the isolation wall 132 may have a width that is slightly greater than or equal to a dimension of each secondary support pillar 133 in a width-wise direction of the isolation wall 132. Here, the width-wise direction of the isolation wall 132 is defined as a direction in a plane parallel to the surface of the first substrate 100 from the outside of the isolation wall 132 toward a center of the region demarcated thereby. Since the isolation wall 132 is etched on one side thereof while the secondary support pillars 133 are etched isotropically, the above width relationship can ensure that the secondary support pillars 133 are substantially etched away with the primary support wall 131 being unaffected. Moreover, the duration of the etching process may be optionally so controlled that both the isolation wall 132 and the secondary support pillars 133 are etched away, with the primary support wall 131 and the area demarcated thereby being not affected at all. This is helpful in improving the integrity of the resonant cavity and thus the BAW resonator's performance. Depending on the design requirements of the BAW resonator, the BAW film stack 120 may have a circular, elliptical, polygonal or otherwise-shaped resonant region (in the cross section in parallelism with the surface of the first substrate 100), and the support structure 130 may be appropriately shaped to save space. FIG. 4 is a schematic plan view of the support structure formed in the method. Referring to FIG. 4, for example, the primary support wall 131 may have a similar shape (e.g., pentagonal, hexagonal, heptagonal, etc.) as the subsequently-formed resonator. Here, by “similar”, it is meant that, when viewed in the plan view, the primary support wall 131 and the resonator are proportionally sized polygons, circles or the like. The shape of the isolation wall 132 may be designed in accordance with that of the primary support wall 131 so that the isolation wall 132 is concentric with, and scaled down relative to, the primary support wall 131. In this way, there is a gap with a consistent width between the primary support wall 131 and the isolation wall 132, leading to space savings. The secondary support pillars 133 are arranged internal to the isolation wall 132. As shown in FIG. 4, in the illustrated embodiment, both the primary support wall 131 and the isolation wall 132 have pentagonal cross-sections in a plane parallel to the surface of the first substrate 100.

In order to reduce or eliminate any adverse impact of the subsequent etching process for removing the isolation wall 132 and the secondary support pillars 133 on the primary support wall 131, according to another embodiment of the present invention, the primary support wall 131, the isolation wall 132 and the secondary support pillars 133 in the support structure 130 are made of different materials. For example, if the subsequent etching process for the secondary support pillars 133 is a wet etching process, it is preferred that the etching rates for the secondary support pillars 133 and the isolation wall 132 are greater than that for the primary support wall 131. In addition, depending on the design requirements, it is also possible that the isolation wall 132 and the secondary support pillars 133 are also made of different materials. In this case, in the wet etching process for the secondary support pillars 133, the etching rates for the secondary support pillars 133 is greater than that for the isolation wall 132, to avoid the liquid etchant from etching through the isolation wall 132 and reaching the primary support wall 131.

By way of examples, several optional embodiments of forming the support structure 130 will be explained below.

In a first optional embodiment, forming the support structure 130 on the BAW film stack 120 involves forming a support layer with a predetermined thickness on the BAW film stack 120. In particular, a chemical vapor deposition process may be carried out on the second electrode layer 123 of the BAW film stack 120 to form thereon an approximately 2 μm to 5 μm thick silicon dioxide film as the support layer, and the surface of the support layer may be then planarized using a CMP process. The support layer is then patterned to form the support structure 130. The patterning process may include exposure, development, etching, demolding and other processes.

In this first embodiment, the primary support wall 131, isolation wall 132 and secondary support pillars 133 are formed by etching the same support layer. Therefore, they are of the same material and etched at the same rate.

In a second optional embodiment, forming the support structure 130 on the BAW film stack 120 includes the steps of: first, forming a first support layer with a predetermined thickness on the BAW film stack 120; then etching the first support layer to form the primary support wall 131; subsequently, depositing a second support layer within the area demarcated by the primary support wall 131 and making a top surface of the second support layer flush with that of the primary support wall 131; and afterward, etching the second support layer to form both the isolation wall 132 and the secondary support pillars 133.

In this second embodiment, the primary support wall 131, the isolation wall 132 and secondary support pillars 133 are formed in different etching processes, and the first support layer from which the primary support wall 131 is fabricated and the second support layer from which both the isolation wall 132 and secondary support pillars 133 are fabricated may be of different materials and thus etched at different rates when the same etching technique is used. The materials of the first and second support layers may be so selected that the secondary support pillars 133 and the isolation wall 132 are etched faster than the primary support wall 131. In this way, the isolation wall 132 may be removed in the same etching process for removing the secondary support pillars 133, and due to the slower etching rate for the primary support wall 131, it will be effectively protected against the etching process proceeding in the isolation wall 132.

In a third optional embodiment, forming the support structure 130 on the BAW film stack 120 includes the steps of: first, forming a first support layer with a predetermined thickness on the BAW film stack 120; then etching the first support layer to form both the primary support wall 131 and the isolation wall 132; subsequently, depositing a second support layer within the area demarcated by the isolation wall 132 and making a top surface of the second support layer flush with that of the primary support wall 131; and afterward, etching the second support layer to form the secondary support pillars 133.

In this third embodiment, the primary support wall 131, the isolation wall 132 and secondary support pillars 133 are formed in different etching processes, and the first support layer from which both the primary support wall 131 and the isolation wall 132 are fabricated and the second support layer from which secondary support pillars 133 are fabricated may be of different materials and thus etched at different rates when the same etching technique is used. The materials of the first and second support layers may be so selected that the secondary support pillars 133 are etched faster than the isolation wall 132 (or the primary support wall 131). In this way, during the etching of the secondary support pillars 133, although the used etchant, e.g., a liquid etchant, may come into contact with the isolation wall 132, since the isolation wall 132 is etched slower, i.e., more resistant to the etching process, than the secondary support pillars 133, it is less likely for the etchant used in the etching process for removing the secondary support pillars 133 to etch through the isolation wall 132 and cause any damage to the primary support wall 131. As a result, the primary support wall 131 is well isolated. Further, compared with the case in which the isolation wall 132 and the secondary support pillars 133 are of the same material (i.e., the first embodiment), the width of the isolation wall 132 may be reduced while providing the same isolation effect.

In a fourth optional embodiment, forming the support structure 130 on the BAW film stack 120 includes the steps of: first, forming a first support layer with a predetermined thickness on the BAW film stack 120; then etching the first support layer to form the primary support wall 131; subsequently, depositing a second support layer within the area demarcated by the primary support wall 131 and making a top surface of the second support layer flush with that of the primary support wall 131; afterward, etching the second support layer to form the isolation wall 132; then depositing a third support layer within the area demarcated by the isolation wall 132 and making a top surface of the third support layer flush with that of the isolation wall 132; and finally, etching the third support layer to form the secondary support pillars 133.

In this fourth embodiment, each of the primary support wall 131, isolation wall 132 and secondary support pillars 133 is formed in a separate etching process, and the first support layer from which the primary support wall 131 is fabricated, the second support layer from which the isolation wall 132 is fabricated and the third support layer from which the secondary support pillars 133 are fabricated may be of distinct materials and thus etched at different rates when the same etching technique is used. For example, the first, second and third support layers may be so selected that, for the etching process for removing the secondary support pillars 133, an etching rate for the secondary support pillars 133 is faster than an etching rate for the isolation wall 132, which is in turn faster than an etching rate for the primary support wall 131. In this way, during the etching of the secondary support pillars 133, although the used etchant, e.g., a liquid etchant, may come into contact with the isolation wall 132, since the isolation wall 132 is etched slower, i.e., more resistant to the etching process, than the secondary support pillars 133, it is less likely for the etchant used in the etching process for removing the secondary support pillars 133 to etch through the isolation wall 132 and cause any damage to the primary support wall 131. As a result, the primary support wall 131 is well isolated. Further, in the subsequent etching process for removing the isolation wall 132 performed after the secondary support pillars 133 have been completely removed, since the primary support wall 131 is even more etch-resistant, the possibility of the used etchant to partially etch away and cause damage to the primary support wall 131 is minimized.

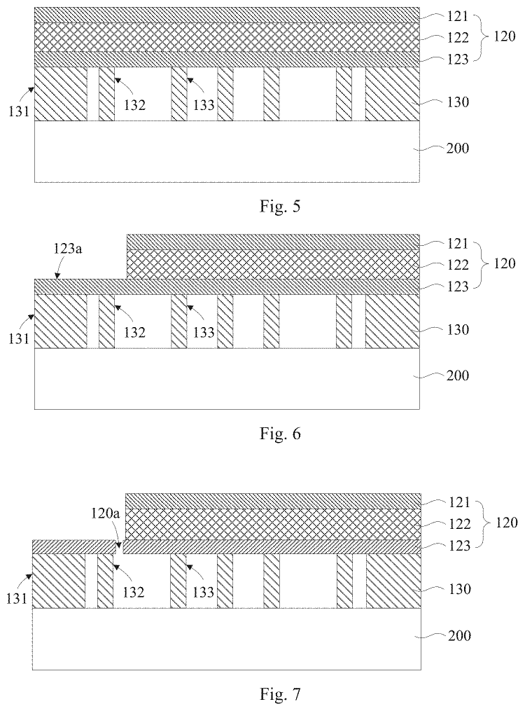

FIG. 5 is a schematic cross-sectional view of a structure resulting from bonding the first substrate to a second substrate in the method according to an embodiment of the present invention. Referring to FIGS. 1 and 5, in step S4, the side of the first substrate 100 with the support structure 130 formed thereon is bonded to the second substrate 200, and the first substrate 100 is then removed.

In the illustrated embodiment, the second substrate 200 is provided as a carrier substrate, and the first substrate 100 is so bonded to the second substrate 200 that the BAW film stack 120 is sandwiched between the two substrates. A backside etching and thinning process may be then performed to substantially remove the first substrate 100, followed by removal of the secondary support pillars 133 and isolation wall 132 from the support structure 130, resulting in the formation of air interfaces on opposing sides of the BAW film stack and the formation of a main body of the FBAR.

The second substrate 200 may be selected from carrier substrates commonly used in the art. Specifically, the second substrate 200 may be fabricated from any suitable substrate material well known to those skilled in the art. Examples of such materials may include at least one of silicon (Si), germanium (Ge), silicon germanium (SiGe), silicon carbide (SiC), silicon germanium carbide (SiGeC), indium arsenide (InAs), gallium arsenide (GaAs), indium phosphide (InP) or other III-V compound semiconductors. Alternatively, the substrate may be a multilayer structure or the like of one or more of those materials. Still alternatively, it may be a silicon on insulator (SOI), strained silicon on insulator (SSOI), strained silicon germanium on insulator (S—SiGeOI), silicon germanium on insulator (SiGeOI), germanium on insulator (GeOI), double side polished (DSP), alumina or like ceramic, quartz, glass or like substrate. In the illustrated embodiment, the second substrate 200 may be, for example, a P-type high-resistance monocrystalline silicon wafer with a (100) crystal plane on the top side. Of course, the second substrate 200 may include any other suitable material known in the art.

The bonding of the first substrate 100 to the second substrate 200 may accomplished with a fusion bonding process or a vacuum bonding process capable of forming strong covalent bonds between the surfaces of the second substrate 200 and the support structure 130 on the first substrate 100. In another embodiment of the present invention, the bonding of the first substrate 100 to the second substrate 200 may also be accomplished with an adhesive such as a hot melt adhesive applied to the second substrate 200. A vacuum bonding process may be then performed to bond a top surface of the support structure 130 (i.e., the surface thereof away from the BAW film stack 120) to the surface of the second substrate 200 in a vacuum environment optionally at a pressure of 1 Pa to 105 Pa and a temperature of 150° C. to 200° C. Such a vacuum bonding process can avoid the formation of bubbles and ensure a good bonding result.

After the first substrate 100 is bonded to the second substrate 200, the whole may be flipped over so that the second substrate 200 serves as a carrier substrate. With the support structure 130 and the BAW film stack 120 having been transferred onto the second substrate 200, the first substrate 100 may be stripped away.

The first substrate 100 may be removed using a backside etching and thinning process with the isolation layer 110 serving as an etch stop layer. This can avoid any adverse impact on the BAW film stack 120, and at the point of removal of the first substrate 100, the thickness of the isolation layer 110 may be significantly reduced, or the whole isolation layer 110 may be removed. For this reason, it is no longer shown in FIG. 5. In another embodiment, the first substrate 100 may be removed using a chemical mechanical polishing process, along with the isolation layer 110. Optionally, when it is taken into consideration to protect the BAW film stack 120 with the isolation layer 110, the isolation layer 110 may be alternatively partially retained. In this case, the remaining thickness of the isolation layer 110 may be determined by a processing limit of the employed chemical mechanical polishing equipment, e.g., 1000 Å. In yet another embodiment, the removal of the first substrate may be accomplished with a suitable process selected according to the material properties of the isolation layer 110 and the first substrate 100. For example, in case of the isolation layer 110 being made of a light-curing adhesive, a chemical reagent may be used to dissolve the light-curing adhesive, separating the first substrate 100 from the BAW film stack 120 and thus allowing removal of the first substrate 100. When the isolation layer 110 is made of a hot melt adhesive, a heat release process such as a thermal treatment may be employed to make the hot melt adhesive lose its adhesion, thus separating the first substrate 100 from the BAW film stack 120 and allowing removal of the first substrate 100. Furthermore, when the isolation layer 110 is a stack of an etch stop layer and a sacrificial layer made of a laser release material, the sacrificial layer may be removed by a laser ablation process, allowing the first substrate 100 to be stripped away. In this case, the etch stop layer in the isolation layer 110 can function as a protective layer for the BAW film stack 120 in the laser ablation process.

As shown in FIG. 5, as a result of step S4, there are air interfaces on both sides of the BAW film stack 120 on the second substrate 200 (i.e., the opposing sides in the thickness-wise direction). Supported by the multiple features of the support structure 130, the BAW film stack 120 is stable and does not tend to collapse when undergoing various processes performed thereon (e.g., patterning). This allows for reduced process control complexity. After the completion of each process step that requires the BAW film stack 120 to be highly stable, the secondary support pillars 133 and the isolation wall 132 may be removed.

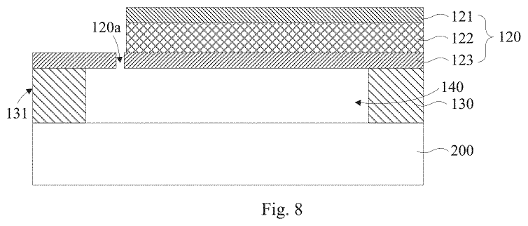

Referring to FIGS. 6 and 7, subsequent to the removal of the first substrate 100, step S5 is carried out to form a release window 120a in the BAW film stack 120, which brings a space delimited by the isolation wall 132 into communication with the outside.

Optionally, after the first substrate 100 has been removed in step S4, the first electrode layer 121 and piezoelectric layer 122 in the BAW film stack 120 may be partially removed using a cutting process or a photomask-based process, resulting in the formation of a peripheral trimmed region 123a, in which part of the second electrode layer 123 is exposed. The peripheral trimmed region 123a may have a side wall that is perpendicular to a top surface of the second electrode layer 123 or slanted at the top towards the center of the area demarcated by the isolation wall 132. The peripheral trimmed region 123a may be partially overlapped with the area demarcated by the isolation wall 132 along the thickness-wise direction thereof. In the overlap between the peripheral trimmed region 123a and the area demarcated by the isolation wall 132, there may be a relatively small film thickness, which enables easy formation of the release window in the BAW film stack 120 and allows a relative large size of the release window. This allows the secondary support pillars 133 and isolation wall 132 to be subsequently removed easily and efficiently.

Additionally, after the first substrate 100 has been removed in step S4, the BAW film stack 120 may be optionally patterned (e.g., by a series of photolithography and etching processes) to form top and bottom electrodes, as well as both a resonant region and a non-resonant region above the area demarcated by the primary support wall 131. The BAW film stack 120 in the resonant region may serve as a resonant structure of the FBAR device being fabricated. In addition, after the formation of the top and bottom electrodes, for example, a metal lift-off technique may be employed to form a metal bonding layer outside the resonant region, which is configured to allow the subsequent bonding of a third substrate serving as a cap substrate on the side of the BAW film stack 120 away from the second substrate 200. With the support from the support structure 130, the films within the boundary of the support structure 130 will not be pressured to experience an excessive degree of downward deformation or be broken in the processes involved in the formation of the top and bottom electrodes and the metal bonding layer. In alternative embodiments of the present invention, the formation of the BAW film stack 120 on the first substrate 100 in step S2 may involve: patterning (e.g., by photolithography and etching processes) the first electrode layer 121 to form the top electrode of the BAW resonator before the piezoelectric layer 122 is formed thereon; patterning (e.g., by photolithography and etching processes) the piezoelectric layer 122 to form a piezoelectric layer in the resonant region of the BAW resonator before the second electrode layer 123 is formed thereon; and patterning (e.g., by photolithography and etching processes) the second electrode layer 123 to form the bottom electrode of the BAW resonator before the support material is formed thereon. It will be appreciated that, in particular embodiments, it is also possible to pattern any one, any two or all of the first electrode 121, piezoelectric 122 and second electrode 123 layers in the BAW film stack 120 in step S2 and pattern all the other layer(s) after the first substrate is removed in step S4.

In the illustrated embodiment, the method may further include, subsequent to the removal of the first substrate 100 and prior to the formation of the release window 120a, a first sub-step in which the first electrode layer 121 and the piezoelectric layer 122 are etched using a photomask with a first pattern so that the side of the second electrode layer 123 away from the second substrate is exposed (as shown in FIG. 6) and the exposed portion of the second electrode layer encompasses part of the area demarcated by the isolation wall 132; and a subsequent second sub-step in which the exposed portion of the second electrode layer 123 is etched using a photomask with a second pattern to form the release window 120a in the area demarcated by the isolation wall 132 (as shown in FIG. 7).

In other embodiments of the present invention, the side of the second electrode layer 123 away from the second substrate may be exposed during the formation of the peripheral trimmed region 123a or of the top and bottom electrodes. Forming the release window 120a in the exposed portion of the second electrode layer 123 can reduce process complexity while avoiding imposing any adverse impact on the resonant region.

In particular, the release window 120a may extend through the BAW film stack 120 into a gap between the isolation wall 132 and one secondary support pillar. Alternatively, the release window 120a may extend through the BAW film stack 120 so that the top of the secondary support pillars 133 is partially exposed. The formation of the release window 120a may be accomplished with a dry etching or a wet etching. Examples of the dry etching process may include, but are not limited to, reactive-ion etching (RIE), ion beam etching, plasma etching and like processes. For example, the release window 120a may be formed by performing a reactive-ion etching process using a fluorine-based gaseous etchant on the exposed portion of the second electrode layer 123. The fluorine-based gaseous etchant may include at least one of CF₄, CHF₃, C₂F₆, CH₂F₂, C₄F₈, NF₃ and SF₄, and the process may be carried out at a power level of 0-500 W in order to ensure a good yield. Alternatively, the release window 120a may be formed in the area demarcated by the isolation wall 132 by performing a laser drilling process on the second electrode layer 123 exposed in the peripheral trimmed region 123a.

In other embodiments of the present invention, instead of forming the peripheral trimmed region 123a, the release window 120a may be directly formed in the BAW film stack 120 so as to extend through the first electrode 121, piezoelectric 122 and second electrode 123 layers. In this case, the release window 120a may be formed using an etching process including multiple steps for individually etching through the first electrode 121, piezoelectric 122 and second electrode 123 layers. The size of the resulting release window 120a may be large enough to allow easy evacuation of unwanted reaction by-products from the etching process from the inside of the support structure via the window. For example, the window may be a circular aperture with a diameter ranging from 10 μm to 30 μm, or a square aperture with a side length of about 10-30 μm.

In order to minimize any adverse impact of the process for removing the secondary support pillars 133 on the primary support wall 131, an orthographic projection of the release window 120a on the surface of the second substrate 200 is desirably within the area demarcated by the isolation wall 132. In other words, a gaseous or liquid etchant may be introduced through the release window 120a and react with the isolation wall 132 and secondary support pillars 133 to remove the secondary support pillars 133 from the space delimited by the isolation wall 132.

The release window 120a may have an opening size depending on the area where the release window is allowed to be formed. Moreover, more than one release window 120a may be formed. Optionally, in order to expedite the removal of the secondary support pillars 133 and isolation wall 132, two or more release windows 120a may be formed in the BAW film stack 120. The multiple release windows 120a may be scattered across the second electrode layer 304 in the area demarcated by the isolation wall 132. Optionally, each release window 120a may be formed at a marginal location of the area demarcated by the isolation wall 132. This avoids imposing any adverse impact on the resonant region, allows a high Q value of the resulting BAW resonator, and facilitates easy evacuation of undesirable substances resulting from subsequent etching and cleaning processes from the cavity and drying of the cavity. Further, this can minimize the areas of possible parasitic devices.

Referring to FIG. 8, in step S6, the secondary support pillars 133 and the isolation wall 132 are removed via the release window 120a.

Depending on the material(s) of the secondary support pillars 133 and the isolation wall 132, they can be removed either by wet or dry etching. In the former case, for example, if the secondary support pillars and isolation wall 132 are made of silicon oxide, an etching solution include a liquid etchant that etches silicon oxide, such as dilute hydrochloric acid, buffered oxide etchant (BOE) or dilute hydrofluoric acid (DHF), may be introduced through the release window 120a into the space delimited by the isolation wall together with the second substrate 200 and the second electrode layer 123 to remove the secondary support pillars 133 and the isolation wall 132. The BOE solution may be a mixture of hydrofluoric acid (HF), ammonium fluoride (NH4F) and wafer. For example, it may be obtained by mixing 40% NH4F, 49% HF and H₂O at a ratio in the range from 10:1:0 to 200:1:10. The DHF solution may be prepared by mixing 49% HF and H₂O at a ratio of, for example, from 30:1 to 500:1. When introduced into the space delimited by the isolation wall 132 and the BAW film stack 120 via the release window 120a, the liquid etchant may come into contact with side walls of the isolation wall 132 and the secondary support pillars 133. Alternatively, it may first come into contact with the top of the secondary support pillar 133 exposed in the release window 120a and then flow through gaps surrounding the secondary support pillar 133 and reach the side walls of any other secondary support pillar 133, if present, and of the isolation wall 132. Further, a process for removing the secondary support pillars 133 and the isolation wall 132 using a BOE or DHF solution may include a short over-etching period (i.e., a cleaning period) for initial cleaning of the cavity delimited by the primary support wall 131 with the BOE or DHF solution through evacuating by-product particles, metal ions and other contaminants resulting from the etching process. This allows a good cleaning effect of the cavity within a short period of time and results in an addition increase in the performance of the resulting device.

Desirably, it shall be taken into consideration that the piezoelectric layer 122, second electrode layer 123 or first electrode layer 121 shall be prevented from any damage during the removal of the secondary support pillars 133 and the isolation wall 132. To this end, it may be appropriate to choose a liquid etchant with a relatively high etch rate ratio of the secondary support pillars 133 and isolation wall 132 to the BAW film stack. Such a liquid etchant can remove the secondary support pillars 133 and the isolation wall 132 while causing minimal or no damage to the BAW film stack.

In another embodiment of the present invention, the secondary support pillars 133 are made of a material easy to be ashed away, such as photoresist, dry film or amorphous carbon. In this case, after the other area than that of the release window 120a is covered by a protective layer, a plasma processing gas may be introduced through the release window 120a into the space delimited by the second substrate 200, the second electrode layer 123 and the isolation wall 132 to remove the secondary support pillars 133. Specific parameters of this process may be determined according to the etching technique used and the requirements of the actual application.

In the illustrated embodiment, during the etching process for removing the secondary support pillars 133, although the isolation wall 132 that is exposed to the liquid etchant or gas etchant may be etched thereby, the possibility of the primary support wall 131 being eroded is minimized due to the blockage provided by the isolation wall 132. Through controlling the number, width of such isolation walls as well as the duration of the etching process for the isolation walls, the isolation wall 132 may be removed simultaneously with the secondary support pillars 133 in step S6. Alternatively, after the secondary support pillars 133 have been completely removed, the etching process may be continued to further remove the isolation wall 132. In other words, the secondary support pillars 133 and the isolation wall 132 may be removed successively. Desirably, the etching reaction is stopped as soon as possible after the isolation wall 132 has been removed, in order to avoid the primary support wall 131 from being affected due to an excessively long duration of the etching process.

After the secondary support pillars 133 and the isolation wall 132 are removed, the second substrate 200, primary support wall 131 and BAW film stack 120 together delimit a cavity 140 acting as a resonant cavity of the BAW resonator. With the above method, no significant variations in the boundary or shape of the cavity 140 will be caused by the above-discussed etching process. That is, the cavity 140 can be fabricated with high consistency, which is favorable to the performance of the BAW resonator.

Optionally, following the removal of the secondary support pillars 133 and isolation wall 132, the cavity 140 may be cleaned (i.e., rinsed) with deionized water injected therein via the release window 120a and dried by further injecting therein gaseous isopropyl alcohol (IPA) through the release window 120a, which enables complete removal of any residual liquid from the cavity 140, ensuring good performance of the resulting resonator. In addition, thanks to the presence of the release window 120a, the inside and outside of the cavity 140 are kept in communication with each other during the cleaning and drying of the cavity 140, resulting in a balance between internal and external pressures of the cavity 140 and avoid cracking of the cavity 140 under an excessively large difference between the pressures.

The cavity 140, together with the BAW film stack and the second substrate 200, constitutes a main body of the resonator. Subsequently, a third substrate may be bonded (as a cap substrate) above the primary support wall 131, with a clearance left between the BAW film stack 120 and the third substrate. The clearance serves as another cavity of the BAW resonator, and is in communication with the cavity 140. The third substrate is provided to encapsulate and protect the main body. Therefore, the secondary support pillars 133 and isolation wall 132 of the support structure can always provide support throughout the various processes involved in the fabrication of the resonator until they are removed prior to the bonding of the third substrate. In the illustrated embodiment, the release window may be located within the area encompassed by the third substrate.

Further, solder pads electrically connected to the first and second electrode layers 121 and 123 may be subsequently formed on the third substrate on both sides of the resonant region, thus completing the FBAR. The first electrode layer 121 may serve as an input or output electrode for receiving or providing electrical signals such as radio-frequency signals. For example, if the patterned second electrode layer 123 is used as an input electrode, the patterned first electrode layer 121 may act as an output electrode. If the patterned second electrode layer 123 is used as an output electrode, the patterned first electrode layer 121 may act as an input electrode. The piezoelectric layer 104 is adapted to convert electrical signals incoming from the patterned first electrode layer 121 or second electrode layer 123 into bulk acoustic waves, for example, by virtue of physical vibration. The support structure and cavity fabricated using the above-described method both have enhanced reliability, which provides for improved performance of the resulting BAW resonator.

In embodiments of the present invention, there is also provided a FBAR fabricated using the above method. The FBAR includes a second substrate 200, a BAW film stack above the second substrate 200 and a support structure between the BAW film stack and the second substrate 200. The support structure includes a primary support wall 131, and the second substrate 200, the primary support wall 131 and the BAW film stack together delimit a cavity 140. The BAW film stack is situated in contact with the support structure above the cavity 140. The above method provides for higher reliability of the cavity 140 and hence of the resulting FBAR, which helps in obtaining improved resonant performance.

In embodiments of the present invention, there is also provided a filter including at least one FBAR, which is fabricated using a method including the above method. The filter may be an RF filter. The above improved method allows for enhanced resonator performance and reliability, helping in improving the filter's performance and yield.

The method and device embodiments disclosed herein are described in a progressive manner, with the description of each succeeding embodiment focusing on its differences from one or more preceding embodiments, and reference may be made therebetween whenever appropriate.

The foregoing description merely explains and illustrates a few preferred embodiments of the present invention and is not intended to limit its scope in any sense. In light of the teachings disclosed above, any person of skill in the art may make various changes and modifications to the disclosed embodiments without departing from the scope of the present invention. Accordingly, any and all such simple changes, equivalent variations and modifications made to the above embodiments in light of the foregoing teachings without departing from the scope of the present invention are intended to fall within the scope.

What is claimed is:

1. A method for forming a film bulk acoustic resonator, comprising:
providing a first substrate;
forming an isolation layer on the first substrate and a bulk acoustic wave film stack on the isolation layer;
forming a support structure on the bulk acoustic wave film stack, the support structure comprising, form outside to inside, a primary support wall, an isolation wall, and a secondary support pillar, which are disposed across a top surface of the bulk acoustic wave film stack, both the primary support wall and the isolation wall being annular, the isolation wall being internal to the primary support wall, the secondary support pillar being internal to the isolation wall;
bonding a side of the first substrate with the support structure formed thereon to a second substrate and removing the first substrate;
forming a release window in the bulk acoustic wave film stack, which brings a space delimited by the isolation wall into communication with a space outside the delimited space; and
removing both the secondary support pillar and the isolation wall via the release window.

2. The method for forming a film bulk acoustic resonator according to claim 1, wherein forming the support structure on the bulk acoustic wave film stack comprises steps of:
forming a support layer with a predetermined thickness on the bulk acoustic wave film stack; and
etching the support layer to form the support structure.

3. The method for forming a film bulk acoustic resonator according to claim 2, wherein the isolation wall has a width that is greater than or equal to a dimension of the secondary support pillar along the width-wise direction of the isolation wall.

4. The method for forming a film bulk acoustic resonator according to claim 1, wherein forming the support structure on the bulk acoustic wave film stack comprises steps of:
forming a first support layer with a predetermined thickness on the bulk acoustic wave film stack;
etching the first support layer to form the primary support wall;
forming a second support layer in an area demarcated by the primary support wall, the second support layer having a top surface flush with a top surface of the primary support wall; and
etching the second support layer to form the isolation wall and the secondary support pillar.

5. The method for forming a film bulk acoustic resonator according to claim 4, wherein the primary support wall is made of a material other than a material of which the isolation wall is made, and wherein the secondary support pillar is removed by an etching process in which the secondary support pillar and the isolation wall are etched at a rate faster than a rate at which the primary support wall is etched.

6. The method for forming a film bulk acoustic resonator according to claim 1, wherein forming the support structure on the bulk acoustic wave film stack comprises steps of:
forming a first support layer with a predetermined thickness on the bulk acoustic wave film stack;
etching the first support layer to form the primary support wall and the isolation wall;
forming a second support layer in an area demarcated by the isolation wall, the second support layer having a top surface flush with a top surface of the primary support wall; and
etching the second support layer to form the secondary support pillar.

7. The method for forming a film bulk acoustic resonator according to claim 6, wherein the isolation wall is made of a material other than a material of which the secondary support pillar is made, and wherein the secondary support pillar is removed by an etching process in which the secondary support pillar is etched at a rate faster than a rate at which the isolation wall is etched.

8. The method for forming a film bulk acoustic resonator according to claim 1, wherein forming the support structure on the bulk acoustic wave film stack comprises steps of:
forming a first support layer with a predetermined thickness on the bulk acoustic wave film stack;
etching the first support layer to form the primary support wall;
forming a second support layer in an area demarcated by the primary support wall, the second support layer having a top surface flush with a top surface of the primary support wall;
etching the second support layer to form the isolation wall;
forming a third support layer in an area demarcated by the isolation wall, the third support layer having a top surface flush with a top surface of the isolation wall; and
etching the third support layer to form the secondary support pillar.

9. The method for forming a film bulk acoustic resonator according to claim 8, wherein a material of which the primary support wall is made, a material of which the isolation wall is made, and a material of which the secondary support pillar is made are different from each other, and wherein the secondary support pillar is removed by an etching process in which the secondary support pillar is etched at a rate faster than a rate at which the isolation wall is etched, and the rate at which the isolation wall is etched is faster than a rate at which the primary support wall is etched.

10. The method for forming a film bulk acoustic resonator according to claim 1, wherein the bulk acoustic wave film stack comprises a first electrode layer, a piezoelectric layer and a second electrode layer, which are sequentially stacked one above another away from the isolation layer.

11. The method for forming a film bulk acoustic resonator according to claim 10, further comprising, subsequent to the removal of the first substrate and prior to the formation of the release window:
removing part of the first electrode layer and part of the piezoelectric layer so that a portion of the second electrode layer is exposed from a side thereof away from the second substrate and the exposed portion of the second electrode layer comprises a portion in an area delimited by the isolation wall; and
etching the exposed portion of the second electrode layer to form the release window in the bulk acoustic wave film stack within the area delimited by the isolation wall.

12. The method for forming a film bulk acoustic resonator according to claim 1, wherein at least two release windows are formed in the bulk acoustic wave film stack.

13. The method for forming a film bulk acoustic resonator according to claim 1, wherein within an area delimited by the isolation wall, the release window is closer to the isolation wall than to a central region.

14. The method for forming a film bulk acoustic resonator according to claim 1, wherein in the support structure, two or three isolation walls are formed one within another between the primary support wall and the secondary support pillar.

15. The method for forming a film bulk acoustic resonator according to claim 1, wherein both the secondary support pillar and the isolation wall are removed via the release window using a wet etching process.

16. The method for forming a film bulk acoustic resonator according to claim 1, wherein there is a gap with a consistent width between the isolation wall and the primary support wall.

17. The method for forming a film bulk acoustic resonator according to claim 1, wherein the isolation wall has a pentagonal, hexagonal or heptagonal shape in a plane parallel to a surface of the first substrate.

18. The method for forming a film bulk acoustic resonator according to claim 1, wherein each of the primary support wall, the isolation wall and the secondary support pillar has a height in the range of from 2 μm to 5 μm.
